(19) United States
(12) Patent Application Publication
(10) Pub. No.: US 2019/0074226 A1
(43) Pub. Date: Mar. 7, 2019

(54) MANUFACTURING METHOD FOR SEMICONDUCTOR DEVICE

(71) Applicants: Semiconductor Manufacturing International (Shanghai) Corporation, Shanghai (CN); Semiconductor Manufacturing International (Beijing) Corporation, Beijing (CN)

(72) Inventors: ZhanKui Zhu, Shanghai (CN); FangYu Zhang, Shanghai (CN); YunZe Shi, Shanghai (CN); Peng Zhao, Shanghai (CN)

(73) Assignees: Semiconductor Manufacturing International (Shanghai) Corporation, Shanghai (CN); Semiconductor Manufacturing International (Beijing ) Corporation, Beijing (CN)

(21) Appl. No.: 16/032,827

(22) Filed: Jul. 11, 2018

(30) Foreign Application Priority Data
Sep. 1, 2017 (CN) 201710778300.6

(51) Int. Cl. H01L 21/8238; H01L 21/768; H01L 21/302; H01L 21/027; H01L 29/165

(52) U.S. Cl. CPC H01L 21/823828; H01L 21/76832; H01L 29/165; H01L 21/0275; H01L 21/302

(57) ABSTRACT

The present application relates to the field of semiconductor technologies, and discloses a manufacturing method for a semiconductor device. The method may include: providing a substrate structure, the substrate structure including: a substrate which includes a first region and a second region; and a first gate structure which is positioned on the first region and used for a first device; forming an etching protection layer on the surface of the substrate structure; forming a mask layer on the etching protection layer above the second region, the mask layer comprising a polymer; performing dry etching, so that the first region on both sides of the first gate structure is etched to form first indentations and that the etching protection layer on the surface of the first gate structure is removed; removing the mask layer to form a semiconductor structure; illuminating the semiconductor structure with light; and performing wet etching, so that the first indentations become second indentations. The present application can reduce an impact of a polymer residue on device performance.

### RELATED APPLICATIONS

The present application claims priority to Chinese Patent Appln. No. 201710778300.6, filed Sep. 1, 2017, the entire disclosure of which is hereby incorporated by reference.

### BACKGROUND

### Technical Field

The present application relates to the field of semiconductor technologies, and in particular, to a manufacturing method for a semiconductor device.

### Related Art

During manufacturing of an integrated circuit, a polymer residue may be caused by various reasons. The polymer residue may affect performance of a device. With the development of the integrated circuit manufacturing process, a critical dimension of a device has become smaller and an impact of the polymer residue on device performance has become more obvious.

Therefore, it is desirable to provide a technical solution that can reduce an impact of a polymer residue on device performance.

### SUMMARY

An objective of the present application is to reduce impact of a polymer residue on device performance.

In one aspect of the present application, a manufacturing method for a semiconductor device is provided. The manufacturing method may include: providing a substrate structure, the substrate structure including: a substrate which includes a first region and a second region; and a first gate structure which is positioned on the first region and used for a first device; forming an etching protection layer on a surface of the substrate structure; forming a mask layer on the etching protection layer above the second region, the mask layer comprising a polymer; performing dry etching, so that the first region on both sides of the first gate structure is etched to form first indentations and that the etching protection layer on the surface of the first gate structure is removed; removing the mask layer to form a semiconductor structure; illuminating the semiconductor structure with light; and performing wet etching, so that the first indentations become second indentations.

In some implementations, the first device includes a metal oxide semiconductor (MOS) device.

In some implementations, the MOS device includes a p-channel metal oxide semiconductor (PMOS) device.

In some implementations, the method further includes: epitaxially growing SiGe in the second indentations.

In some implementations, the method further includes: before epitaxially growing SiGe in the second indentations, illuminating the second indentations with light.

In some implementations, the substrate structure further includes a second gate structure which is positioned on the second region and used for a second device.

In some implementations, the second device includes an n-channel metal oxide semiconductor (NMOS) device.

In some implementations, the light includes a laser.

In some implementations, the laser has a wavelength greater than 380 nm.

In some implementations, the laser has a wavelength range of 10 nm to 380 nm.

In some implementations, the laser has a wavelength less than 10 nm.

In some implementations, the laser includes two or more of a first laser, a second laser and a third laser; the first laser has a wavelength greater than 380 nm; the second laser has a wavelength range of 10 nm to 380 nm; and the third laser has a wavelength less than 10 nm.

In some implementations, the method further includes: performing an asher process after removing the mask layer.

In some implementations, the asher process is performed before the first semiconductor structure is illuminated with light.

In some implementations, the mask layer includes a photoresist.

In some implementations, the etching protection layer includes a silicon nitride or silicon carbide.

In some implementations, an etching agent employed in the wet etching includes tetramethylammonium hydroxide.

In some implementations, the first gate structure includes: a first gate dielectric layer on the first region; a first gate positioned on the first gate dielectric layer; and a first hard mask layer on the surface and side walls of the first gate.

In some implementations, the method further includes: forming a buffer layer on the surface of the substrate structure before the etching protection layer is formed on the surface of the substrate structure.

In some implementations, the second gate structure includes: a second gate dielectric layer on the second region; a second gate positioned on the second gate dielectric layer; and a second hard mask layer on the surface and side walls of the second gate.

In forms of the manufacturing method provided in the present application, the manner of illumination after removal of the mask layer can effectively remove the residual polymer in the first indentations, thereby reducing an impact of the residual polymer on wet etching, so that the shape of the second indentation is a desired shape and an impact on device performance (such as carrier mobility) is reduced. In addition, because the residual polymer in the first indentations is removed, it is unnecessary to perform a next process immediately, so that a waiting time is increased. In addition, the illumination does not adversely affect other performance of a device and is easy to carry out.

Through the following detailed description of exemplary embodiments and implementations of the present application with reference to the accompanying drawings, other features, aspects, and advantages of the present application will become clear.

### BRIEF DESCRIPTION OF THE DRAWINGS

The accompanying drawings, as a part of the specification, illustrate exemplary embodiments and implementations of the present disclosure and, together with the specification, serve to explain the principles of the present application. In the accompanying drawings:

FIG. 1 is a flowchart of a manufacturing method for a semiconductor device according to one form of the present application; and

FIG. 2 to FIG. 8 are schematic diagrams of stages in a manufacturing method for a semiconductor device according to some forms of the present application.

### DETAILED DESCRIPTION

Various exemplary embodiments and implementations of the present application are described in detail with reference to the accompanying drawings. It should be understood that unless otherwise specified, relative layouts, mathematical expressions, and numeric values of components and steps described in these embodiments and implementations should not be construed as a limitation on the scope of the present application.

In addition, it should be understood that for ease of description, sizes of the components shown in the accompanying drawings are not necessarily drawn according to an actual proportional relation. For example, the thickness or width of some layers may be exaggerated with respect to other layers.

The following description about the exemplary embodiments and implementations is for illustrative purpose only, and should by no means be used as any limitation on the present application as well as the application or use thereof.

Technologies, methods, and devices that are known by a person of ordinary skill in the related fields may not be discussed in detail. However, in proper cases, the technologies, methods, and devices should be considered as a part of the specification.

It should be noted that similar reference signs and letters represent similar items in the following accompanying drawings. Therefore, once an item is defined or described in a figure, the item may not be further discussed in the subsequent figures.

The inventor of the present application finds that, impact of a polymer residue on a PMOS is especially evident. In strain engineering, in order to introduce a compressive stress to a channel, it is usually necessary to form, on both sides of a gate, indentations used for epitaxy of a source region and a drain region. Then, SiGe, for example, is epitaxially grown in the indentations to introduce a compressive stress to the channel, so as to improve carrier mobility. However, the inventor finds that the shapes of the indentations for epitaxy of the source region and the drain region are not all desired shapes. For example, the bottoms of some indentations are wider than the bottom of a normal indentation. The shape of an indentation may affect a compressive stress introduced by the epitaxially formed source region and the drain region to the channel, thus affecting carrier mobility of a device.

The inventor investigated to find a cause of the foregoing problem. The inventor finds that, a PMOS device may be manufactured together with other devices, such as an NMOS device. Before indentations for epitaxy of a source region and a drain region are formed by means of etching, a polymer-containing mask layer such as a photoresist may be formed on a region where another device is located. After the mask layer is removed, there may be residual polymer in the indentations. For example, in a subsequent wet etching process, the residual mask layer may be brought into the indentations and therefore the polymer is present in the indentations. For another example, deposition of a waste gas during removal of the mask layer causes the presence of a polymer in the indentations. For yet another example, a polymer is present in air in a sealed container where a chip is located. The presence of a polymer may affect etching of the indentations and therefore the shapes of the formed indentations are not all desired shapes.

In addition, due to the polymer residue in the indentations, it is necessary to perform a next process immediately after removal of the mask layer. A waiting time (Q time) is relatively short. Otherwise, the polymer in the indentations may further accumulate. For example, the polymer in the residual mask layer moves to the indentations.

In addition to the MOS device, other devices may also have the foregoing problem if it is necessary to carry out etching in a particular region to form indentations during manufacturing.

Based on the foregoing considerations, the inventor puts forward the following solution.

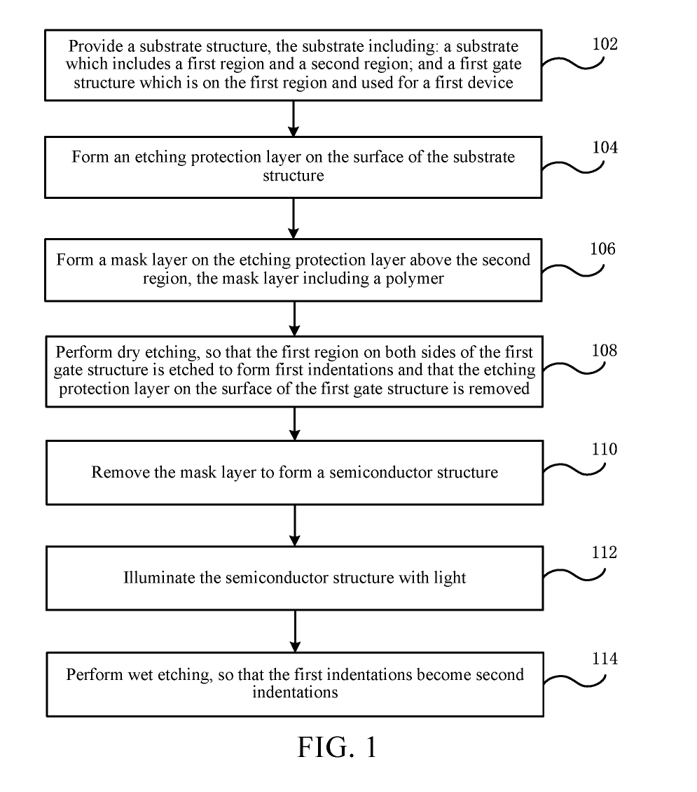

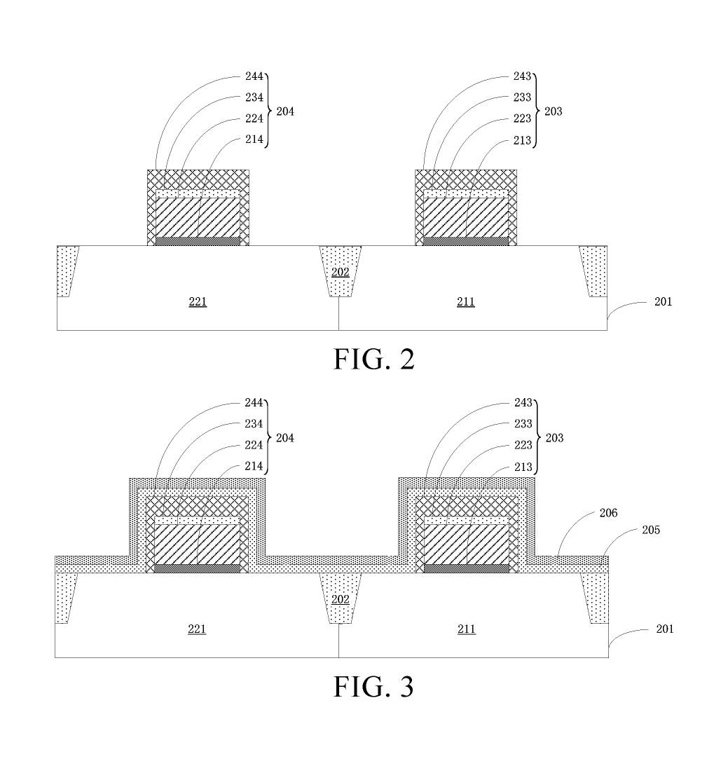

FIG. 1 is a flowchart of a manufacturing method for a semiconductor device according to one form of the present application. FIG. 2 to FIG. 8 are schematic diagrams of stages in a manufacturing method for a semiconductor device according to some forms of the present application.

A manufacturing method for a semiconductor device is described in detail below with reference to FIG. 1 and FIG. 2 to FIG. 8.

As shown in FIG. 1, first, in step 102, a substrate structure is provided.

As shown in FIG. 2, the substrate structure may include a substrate 201. The substrate 201 may be, for example, an element semiconductor substrate such as a silicon substrate or a germanium substrate, or may be a compound semiconductor substrate such as a gallium arsenide substrate. The substrate 201 includes a first region 211 and a second region 221. The first region 211 and the second region 221 may be isolated from each other by an isolation structure 202 (such as a shallow trench isolation structure).

The substrate structure may further include a first gate structure 203 which is on the first region 211 and used for a first device. In some implementations, the first device may be an MOS device. For example, the MOS device may be a PMOS device. However, the present application is not limited thereto. For example, the MOS device may also be an NMOS device.

In some implementations, the first gate structure 203 may include a first gate dielectric layer 213 (such as a silicon oxide) on the first region 211, a first gate 223 (such as polycrystalline silicon) on the first gate dielectric layer 213 and a first hard mask layer 243 (such as a silicon nitride) on the surface and side walls of the first gate 223. In some implementations, the first gate structure 203 may further include a buffer layer 233 such as a silicon oxide between the surface of the first gate 223 and the first hard mask layer 243. However, it should be understood that, the first gate structure 203 is not limited to the structure provided above. For example, in other implementations, the first gate structure 203 may include other layers. For another example, the first hard mask layer 243 may be formed only above the first gate 223, but is not formed on the side walls of the first gate 223.

In some implementations, the substrate structure may further include a second gate structure 204 which is on the second region 221 and used for a second device (such as an NMOS device). In some implementations, the second gate structure 204 may include a second gate dielectric layer 214 (such as a silicon oxide) on the second region 221, a second gate 224 (such as polycrystalline silicon) on the second gate dielectric layer 214 and a second hard mask layer 244 (such as a silicon nitride) on the surface and side walls of the second gate 224. Preferably, the second gate structure 204 may further include a buffer layer 244 such as a silicon oxide between the surface of the second gate 224 and the second hard mask layer 234. Similarly, the second gate structure 204 is not limited to the structure provided above either.

Next, in step 104, an etching protection layer 206 is formed on the surface of the substrate structure, as shown in FIG. 3. In some implementations, the etching protection layer 206 may include a silicon nitride (such as SiN), silicon carbide, or the like.

In some implementations, before the etching protection layer 206 is formed on the surface of the substrate structure, a buffer layer 205 such as a silicon oxide may be first formed on the surface of the substrate structure. The buffer layer 205 can increase a bonding force between the etching protection layer 206 and the first hard mask layer 233 as well as the second hard mask layer 234 on one hand, and on the other hand can protect the first hard mask layer 233 and the second hard mask layer 234 from being etched in a subsequent process.

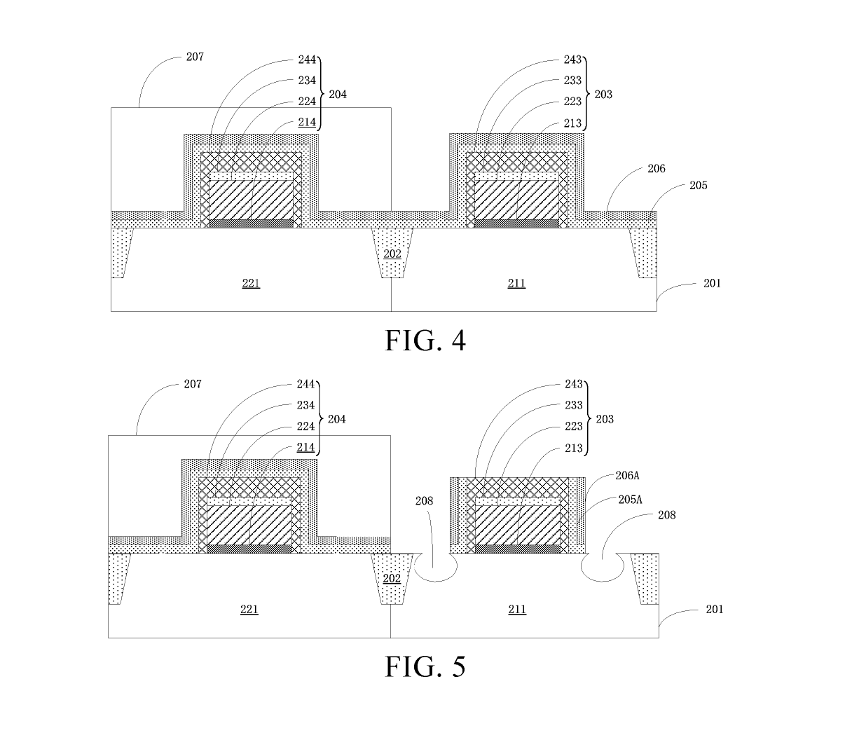

Then, in step 106, a mask layer 207 is formed on the etching protection layer 206 above the second region 221, as shown in FIG. 4. Here, the mask layer 207 contains a polymer. In some implementations, the mask layer 207 may include, but is not limited to, a photoresist. For example, the mask layer 207 may further include other layers such as a bottom anti-reflective coating.

Next, in step 108, dry etching is performed, as shown in FIG. 5. By means of the dry etching, the first region 211 on both sides of the first gate structure 203 is etched to form first indentations 208. The shape of the first indentation 208 may be an ellipse-like shape. The dry etching also removes the etching protection layer 206 on the surface of the first gate structure 203. The remaining etching protection layer 206 on the side wall of the first gate structure 203 serves as a spacer layer 206A.

It should be noted that, when the buffer layer 205 is provided, the dry etching further removes the buffer layer 205 on the surface of the first gate structure 203. The remaining buffer layer 205 on the side wall of the first gate structure 203 serves as a spacer layer 205A. In addition, it can be understood that, the etching protection layer 206 and the buffer layer 205 (if any) on the first region 211 on both sides of the first gate structure 203 are also removed correspondingly.

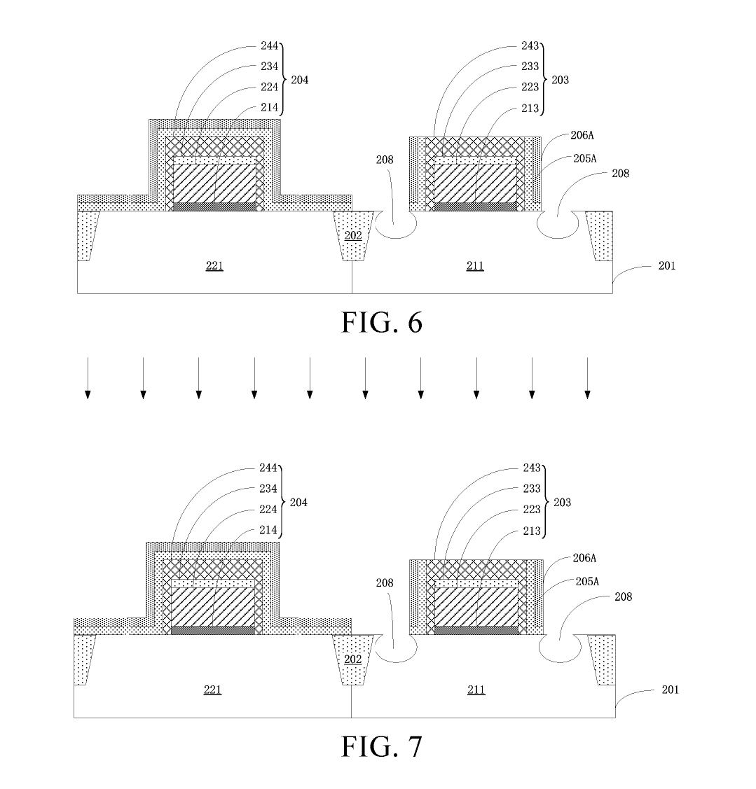

Next, in step 110, the mask layer 207 is removed to form a semiconductor structure as shown in FIG. 6.

Then, in step 112, the semiconductor structure is illuminated with light, as shown in FIG. 7.

When the mask layer 207 is removed, there may be a residue of the mask layer 207. If no other measures are taken, the residual mask layer 207 may move to the indentations 208 in a subsequent wet etching process. Through the step of illuminating the semiconductor structure with light, the polymer in the residual mask layer may be decomposed. It should be understood that, the illumination may cause the polymer, which is present in the first indentations 208 due to various reasons, to decompose. After the illumination, the surface of the first indentation 208 is more suitable for a subsequent process.

In some implementations, the semiconductor structure may be illuminated with a laser. The laser has better directionality and higher energy density, so that the polymer in the residual mask layer is decomposed faster. In some implementations, the wavelength of the laser may be greater than 380 nm, for example, the wavelength is 400 nm, 450 nm, 600 nm or the like. In another implementation, a wavelength range of the laser may be 10 nm to 380 nm, for example, the wavelength is 50 nm, 100 nm, 200 nm, or the like. In yet another implementation, the wavelength of the laser may be less than 10 nm, for example, the wavelength is 5 nm, 8 nm, or the like.

In some implementations, the semiconductor structure may be simultaneously illuminated with lasers having different wavelengths. In an implementation, the laser may include two or more of a first laser, a second laser and a third laser. Here, the wavelength of the first laser is greater than 380 nm; a wavelength range of the second laser is 10 nm to 380 nm; and the wavelength of the third laser is less than 10 nm. For example, the laser may include the first laser and the second laser. In another example, the laser may include the second laser and the third laser. In yet another example, the laser may include the first laser and the third laser. In a further example, the laser may include the first laser, the second laser and the third laser. By simultaneously illuminating the semiconductor structure with the lasers in three different wavelength ranges, the polymer in the residual mask layer 207 can be decomposed faster and more thoroughly.

In some implementations, to better remove the residual polymer, after the mask layer 207 is removed, an asher process may further be performed. A combination of the asher process and illumination facilitates thorough removal of the residual polymer. Here, the asher process may be performed before step 112 or performed after step 112. Preferably, the asher process is performed before step 112. By means of illumination after the asher process, the residual polymer can be removed more thoroughly.

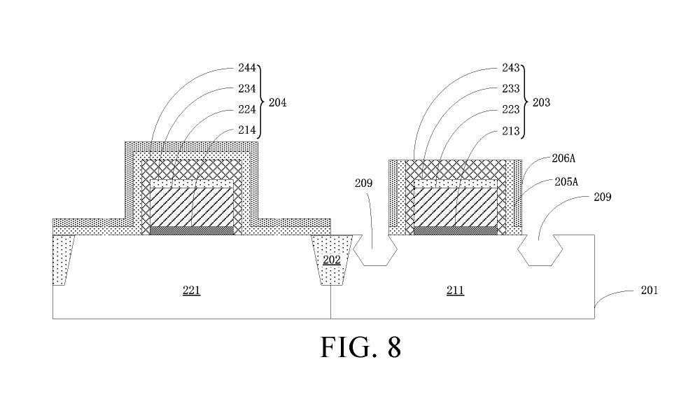

Then, in step 114, wet etching is performed, so that the first indentations 208 become second indentations 209, as shown in FIG. 8. The shape of the second indentation 209 may be, for example, hexagonal or Σ-shaped. In some implementations, an etching agent employed in the wet etching may include tetramethylammonium hydroxide (TMAH) or the like.

After the second indentations 209 are formed, SiGe may further be epitaxially grown in the second indentations 209 to form a source region and a drain region.

In some implementations, before epitaxy of SiGe, the second indentations may be illuminated with light again to further remove the residual polymer in the second indentations 209, so as to avoid impact of the residual polymer on the epitaxy process. For the manner of illumination, reference may be made to the foregoing description and details are not described herein again.

Then, a subsequent process may be performed. For example, indentations for a source region and a drain region of an NMOS device may be formed using forms of the foregoing method provided in the present application. Further, SiC, for example, is epitaxially grown in the formed indentations, thereby forming the source region and the drain region used for the NMOS device.

In forms of the manufacturing method provided in the present application, the manner of illumination after removal of the mask layer can effectively remove the residual polymer in the first indentations, thus reducing an impact of the residual polymer on wet etching, so that the shape of the second indentation is a desired shape and impact on device performance (such as carrier mobility) is reduced. In addition, because the residual polymer in the first indentations is removed, it is unnecessary to perform a next process immediately, so that a waiting time is increased. In addition, the illumination does not adversely affect other performance of a device and is easy to carry out.

Above, forms of a manufacturing method for a semiconductor device according to the embodiments and implementations of the present application have been described in detail. To avoid obstructing the concepts of the present disclosure, some details generally known in the art are not described. According to the foregoing descriptions, a person skilled in the art will understand how to implement the technical solutions disclosed herein. In addition, the embodiments and implementations taught in the disclosure of the specification can be combined freely. A person skilled in the art will understand that the embodiments and implementations described above may be modified without departing from the spirit and scope of the present application as defined by the appended claims.

What is claimed is:

1. A manufacturing method for a semiconductor device comprising:
providing a substrate structure, the substrate structure comprising:
a substrate which comprises a first region and a second region; and
a first gate structure which is positioned on the first region and is used for a first device;
forming an etching protection layer on a surface of the substrate structure;
forming a mask layer on the etching protection layer above the second region, the mask layer comprising a polymer;
performing dry etching, so that the first region on both sides of the first gate structure is etched to form first indentations and so that the etching protection layer on a surface of the first gate structure is removed;
removing the mask layer to form a semiconductor structure;
illuminating the semiconductor structure with light; and
performing wet etching, so that the first indentations become second indentations.

2. The method according to claim 1, wherein the first device comprises a metal oxide semiconductor (MOS) device.

3. The method according to claim 2, wherein the MOS device comprises a p-channel metal oxide semiconductor (PMOS) device.

4. The method according to claim 3, further comprising:
epitaxially growing SiGe in the second indentations.

5. The method according to claim 4, wherein the method further comprises:
before epitaxially growing SiGe in the second indentations, illuminating the second indentations with light.

6. The method according to claim 3, wherein the substrate structure further comprises a second gate structure which is positioned on the second region and used for a second device.

7. The method according to claim 6, wherein the second device comprises an n-channel metal oxide semiconductor (NMOS) device.

8. The method according to claim 1, wherein the light comprises a laser.

9. The method according to claim 8, wherein the laser has a wavelength greater than 380 nm.

10. The method according to claim 8, wherein the laser has a wavelength range of 10 nm to 380 nm.

11. The method according to claim 8, wherein the laser has a wavelength less than 10 nm.

12. The method according to claim 8, wherein:
the laser comprises two or more of a first laser, a second laser and a third laser;
the first laser has a wavelength greater than 380 nm;
the second laser has a wavelength range of 10 nm to 380 nm; and
the third laser has a wavelength less than 10 nm.

13. The method according to claim 1, further comprising:
performing an asher process after removing the mask layer.

14. The method according to claim 13, wherein the asher process is performed before the first semiconductor structure is illuminated with light.

15. The method according to claim 1, wherein the mask layer comprises a photoresist.

16. The method according to claim 1, wherein the etching protection layer comprises a silicon nitride or silicon carbide.

17. The method according to claim 1, wherein an etching agent employed in the wet etching comprises tetramethylammonium hydroxide.

18. The method according to claim 1, wherein the first gate structure comprises:
a first gate dielectric layer on the first region;
a first gate on the first gate dielectric layer; and
a first hard mask layer on the surface and side walls of the first gate.

19. The method according to claim 18, further comprising:
forming a buffer layer on the surface of the substrate structure before the etching protection layer is formed on the surface of the substrate structure.

20. The method according to claim 6, wherein the second gate structure comprises:
a second gate dielectric layer on the second region;
a second gate positioned on the second gate dielectric layer; and
a second hard mask layer on the surface and side walls of the second gate.
